(19) United States
(12) Patent Application Publication
(10) Pub. No.: US 2017/0201076 A1
(43) Pub. Date: Jul. 13, 2017

(54) RACK WITH BUILT-IN POWER DISTRIBUTION UNIT

(71) Applicants: LITE-ON ELECTRONICS (GUANGZHOU) CO., LTD., Guangzhou (CN); LITE-ON TECHNOLOGY CORPORATION, TAIPEI CITY (TW)

(72) Inventors: Shih-Ming Chen, Tainan City (TW); Yuan-Sen Tsai, Tainan City (TW); Wen-Che Tsai, Tainan City (TW)

(21) Appl. No.: 15/085,649

(22) Filed: Mar. 30, 2016

(30) Foreign Application Priority Data
Jan. 7, 2016 (TW) 105200174

(51) Int. Cl. H02B 1/015; H05K 5/00; H02B 1/04; H02G 3/18

(52) U.S. Cl. CPC H02B 1/015; H02G 3/18; H05K 5/0017; H02B 1/04

(57) ABSTRACT

The invention provides a rack with a built-in power distribution unit. The rack with a built-in power distribution unit includes a top, a bottom, the built-in power distribution unit and at least one supporting column. The built-in power distribution unit has a column housing and a plurality of power sockets, wherein the column housing is rotatably configured between the top and the bottom and the plurality of power sockets are configured on the column housing. The least one supporting column is configured between the top and the bottom, supports the top with the built-in power distribution unit, and forms a containing space with the column housing, the top and the bottom.

### RELATED APPLICATIONS

This application claims the benefit of Taiwan Patent Application No. 105200174, filed on Jan. 7, 2016, at the Taiwan Intellectual Property Office, the entire disclosure of which is incorporated herein by reference.

### FIELD OF THE INVENTION

The present invention relates to a rack, specifically a rack with a built-in power distribution unit.

### BACKGROUND OF THE INVENTION

Please refer to FIG. 1 which is a schematic diagram showing a prior rack. The prior rack 10 includes a first column 11 and a second column 12, where the first column 11 has a plurality of holes 111 and the second column 12 has a plurality of holes 121. An external power distribution device 13 includes a plurality of power sockets 131 and a plurality of screws 132. The external power distribution device 13 is configured between the first column 11 and the second column 12, and is fixed to the first column 11 and the second column 12 via the plurality of screws 132, the plurality of holes 111 and the plurality of holes 121. An external network device has network cable 141 and is fixed to the first column 11 and the second column 12 in the same way as the external power distribution device 13. In addition, the plurality of holes 111 of the first column 11 and the plurality of holes 121 of the second column 12 can also be used to fix or fasten the other external devices. In FIG. 1, it can be seen that the external power distribution device 13 is fixed to the two columns (i.e., the first column 11 and the second column 12) of the prior rack 10, and thus takes up the space between the first column 11 and the second column 12 of the prior rack 10. Furthermore, the external power distribution device 13 includes the plurality of sockets 131 to provide power for the external devices in the prior rack 10, and a plurality of power cables 15 in the prior rack 10 cover or obstruct the external devices in the prior rack 10 so as to affect the operation and the exterior view. If the number of the external devices in the prior rack 10 is excessive, it needs more than one external power distribution devices, which takes up more space and causes a mess of the power cables. Hence, it brings up the problems of cable cleaning/cable management and heat dissipation.

In order to circumvent all the above issues, the inventors have proposed an invention “RACK WITH BUILT-IN POWER DISTRIBUTION UNIT.” Using the rack with a built-in power distribution unit of the present invention, the built-in power distribution unit does not take up the space in the rack and thus there the power cables does not affect the operation and the exterior view. Therefore, the present invention saves the space in the rack and increases the efficiency of heat dissipation. The summary of the present invention is described as follows.

### SUMMARY OF THE INVENTION

According to the first aspect of the present invention, a rack with a built-in power distribution unit is provided and includes a top, a bottom, the built-in power distribution unit and at least one supporting column. The built-in power distribution unit has a column housing and a plurality of power sockets, the column housing is rotatably configured between the top and the bottom, and the plurality of power sockets are configured on the column housing. The at least one supporting column is configured between the top and the bottom, collaborates with the built-in power distribution unit to support the top, and forms a containing space with the column housing, the top and the bottom.

Preferably, the built-in power distribution unit further includes a cable clip configured on the column housing, and a power cable passes into the column housing through the cable clip.

Preferably, the cable clip is further configured on an upper end or a lower end of the column housing.

Preferably, the built-in power distribution unit further includes a circuit breaker.

Preferably, the built-in power distribution unit further includes a display interface, and the display interface can be a lighting unit or a display panel.

Preferably, the plurality of power sockets has at least two types, and the built-in power distribution unit further includes a grounding wire.

According to the second aspect of the present invention, a rack with a built-in power distribution unit is provided and includes a top, a bottom and a plurality of supporting columns configured between the top and the bottom and forming a containing space with the top and the bottom, wherein, at least one of the plurality of supporting columns has a housing and the built-in power distribution unit having a plurality of power sockets, the at least one of the plurality of supporting columns is rotatably configured between the top and the bottom, and the plurality of power sockets are configured on the housing.

According to the third aspect of the present invention, a rack with a built-in power distribution unit is provided and includes a bottom, the built-in power distribution unit and at least one supporting column. The built-in power distribution unit has a column housing and a plurality of power sockets configured on the column housing. The at least one supporting column is configured between the top and the bottom. The at least one supporting column the column housing of the built-in power distribution unit and the bottom can be assembled to form a containing space.

Preferably, the rack further includes a rotating mechanism configured to connect the column housing of the built-in power distribution unit and the bottom.

Preferably, the bottom has a square frame.

The present invention provides a rack with a built-in power distribution unit. The built-in power distribution unit has a column housing and power sockets configured on the column housing, which makes the rack have more space inside. In addition, the column housing of the built-in power distribution unit can be a supporting column of the rack, and is able to be rotated so as to change the direction of the power sockets.

The present invention will be more clearly understood through the following descriptions with reference to the drawings:

### BRIEF DESCRIPTION OF THE DRAWINGS

FIG. 1 is a schematic diagram showing a prior rack.

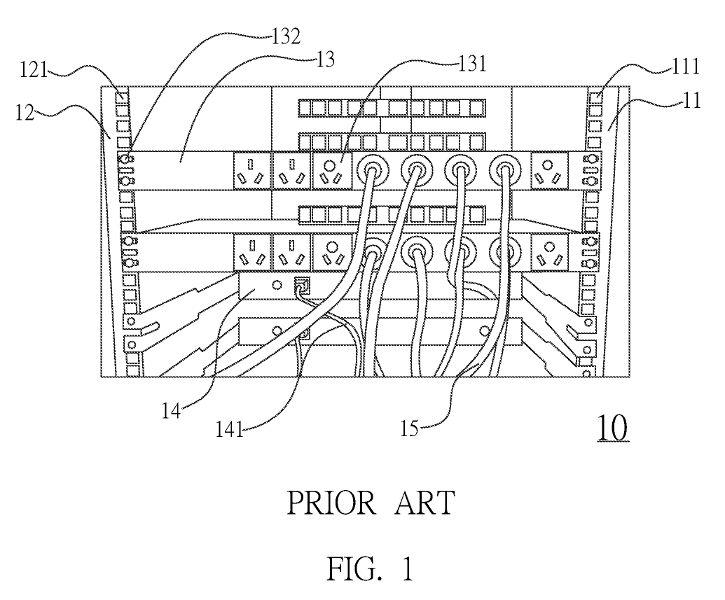

FIG. 2(a) is a schematic diagram showing the first embodiment according to the present invention.

FIG. 2(b) is a schematic diagram showing the first embodiment with the rotated column housing of the built-in power distribution unit according to the present invention.

FIG. 3 is a schematic diagram showing the second embodiment according to the present invention.

FIG. 4 is a schematic diagram showing the third embodiment according to the present invention.

### DETAILED DESCRIPTION OF THE PREFERRED EMBODIMENTS

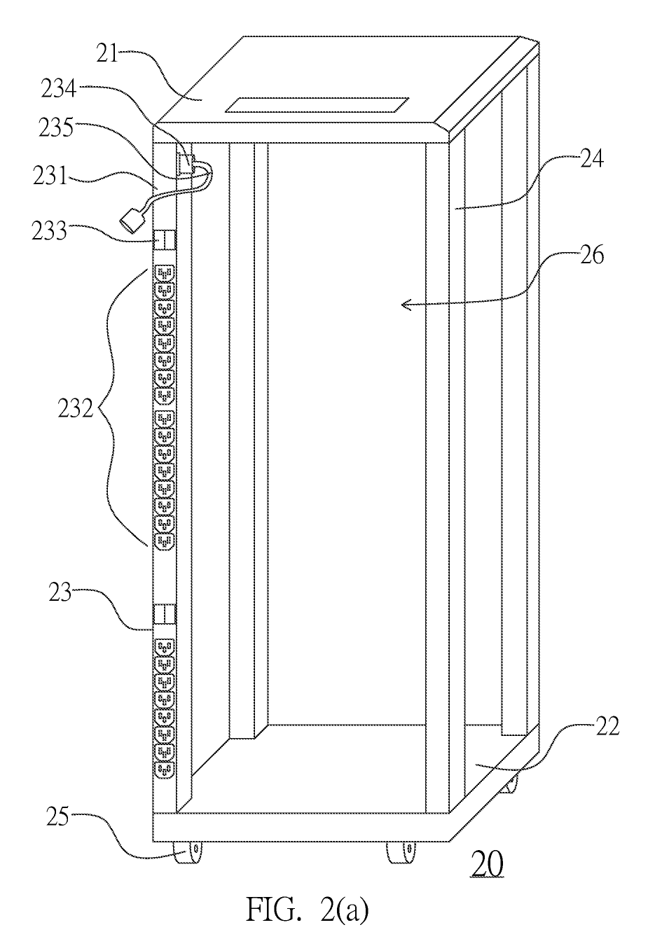

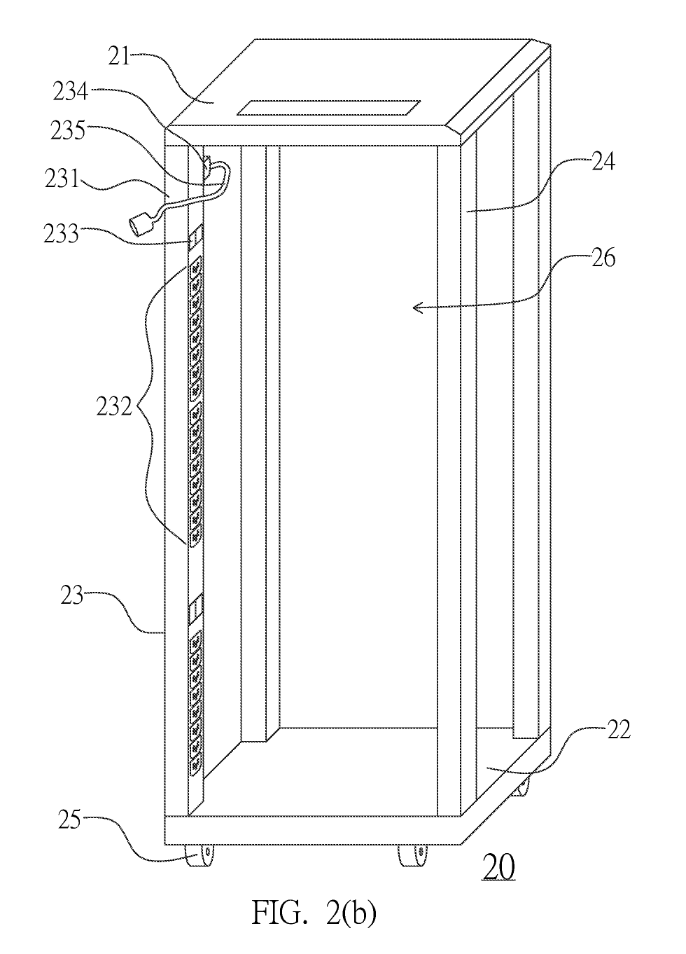

Please refer to FIG. 2(a) which is a schematic diagram showing the first embodiment according to the present invention. In the first embodiment, a rack 20 includes a top 21, a bottom 22, a built-in power distribution unit 23, supporting columns 24 and wheels 25. The built-in power distribution unit 23 has a column housing 231, a plurality of power sockets 232, a circuit breaker (CB) 233, a cable clip 234 and a main power cable 235. In FIG. 2(a), it is seen that the column housing 231 of the built-in power distribution unit 23 and the three supporting columns 24 are configured between the top 21 and the bottom 22 so as to form a containing space 26. In other words, the column housing 231 of the built-in power distribution unit 23 has a supporting function as the supporting column 24 do. The four wheels 25 are configured under the bottom 22 so that the rack 20 can be easily moved to a desired position. As to the built-in power distribution unit 23, the plurality of power sockets 232, the circuit breaker 233 and the cable clip 234 are all configured on the column housing 231. In the other hand, the main power cable 235 passes into the column housing 231 through the cable clip 234, and then the main power cable 235 is protected by the circuit breaker 233 (which provides the protection against overload/overcurrent) before being connected to the plurality of power sockets 232, which distribute power to each of the external devices.

Pease refer to FIG. 2(b) which is a schematic diagram showing the first embodiment with the rotated column housing of the built-in power distribution unit according to the present invention. In the first embodiment, the column housing 231 of the built-in power distribution unit 23 is rotatably configured between the top 21 and the bottom 22. The column housing 231 shown in FIG. 2(b) is that the column housing 231 in FIG. 2(a) is rotated 90 degrees in anticlockwise direction. Accordingly, the plurality of power sockets 232 and the cable clip 234 are rotated 90 degrees anticlockwise as well. Due to the design of the rotatable column housing 231, users have more choices for wire arrangement. Therefore, it is easier to arrange the space.

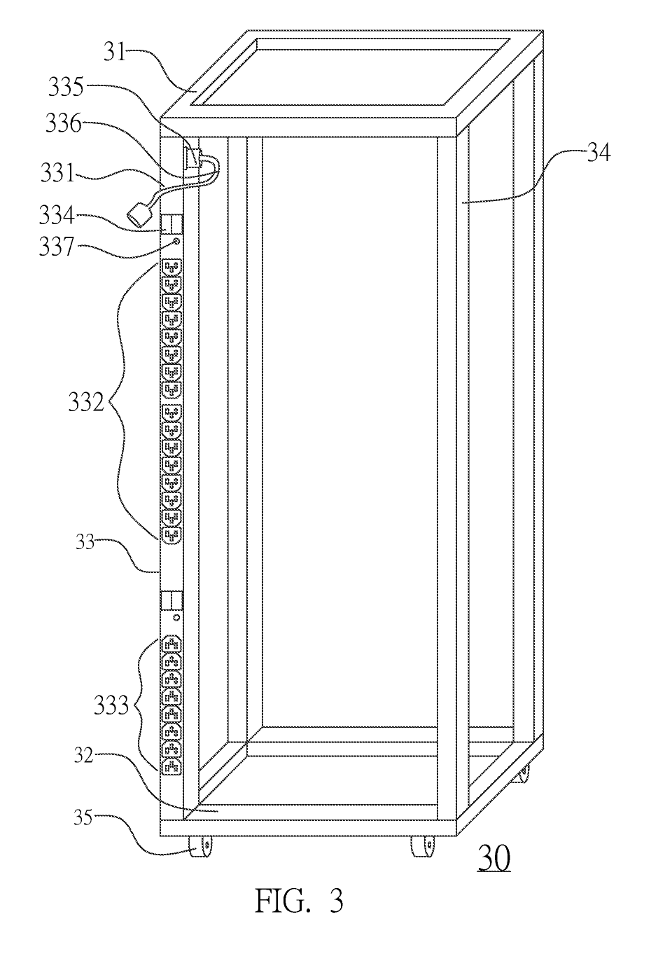

Please refer to FIG. 3 which is a schematic diagram showing the second embodiment according to the present invention. In the second embodiment, a rack 30 includes a top 31, a bottom 32, a built-in power distribution unit 33, supporting columns 34 and wheels 35. The built-in power distribution unit 33 has a column housing 331, a first plurality of power sockets 332, a second plurality of power sockets 333, a circuit breaker 334, a cable clip 335, a main power cable 336 and a display interface 337. It is seen in FIG. 3 that the column housing 331 of the built-in power distribution unit 33 and the three supporting columns 34 are configured between the top 31 and the bottom 32, both the top 31 and the bottom 32 have their own square frame structures, and the four wheels 35 are configured under the bottom 32. As to the built-in power distribution unit 33, the first plurality of power sockets 332, the second plurality of power sockets 333, the circuit breaker 334 and the cable clip 335 are all mounted in the column housing 331, and the main power cable 336 is connected to the circuit breaker 334, display interface 337, the first plurality of power sockets 332 and the second plurality of power sockets 333 in the column housing 331 through the cable clip 335 so as to provide power for the external devices. The first plurality of power sockets 332 and the second plurality of power sockets 333 are two different set of power sockets with different types or specifications. The display interface 337 can show the status of the first plurality of power sockets 332. For example, if the display interface 337 is a lighting unit, the brightness of the lighting unit represents that the first plurality of power sockets 332 are supplying power normally, the darkness of the lightning unit represents that the first plurality of power sockets 332 do not supply power, and the flashing of the lightning unit represents that the first plurality of power sockets 332 is abnormal or has a breakdown/malfunction.

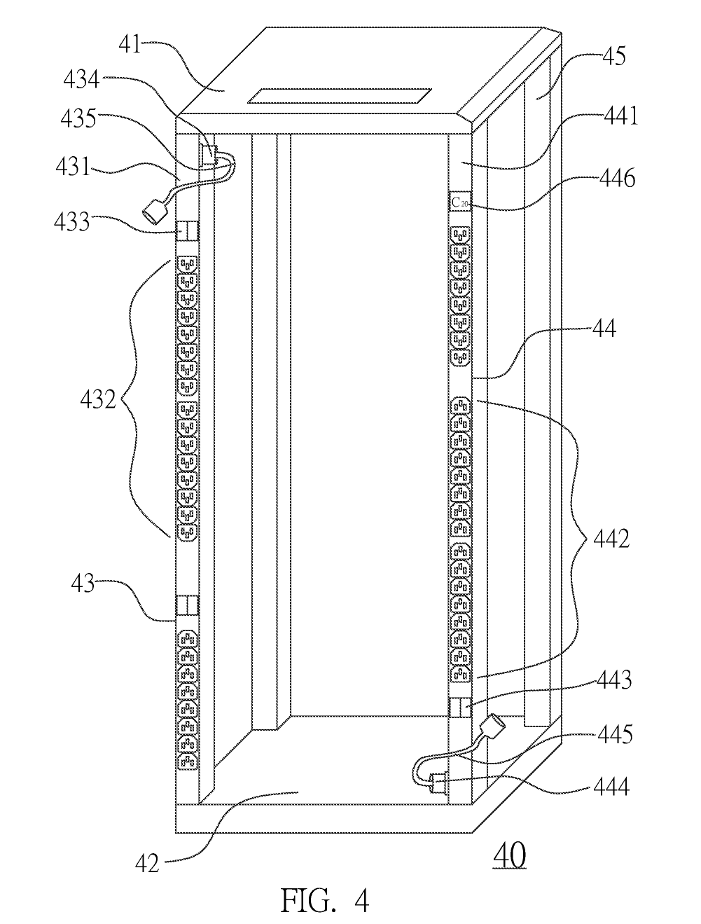

Please refer to FIG. 4 which is a schematic diagram showing the third embodiment according to the present invention. In the third embodiment, a rack 40 includes a top 41, a bottom 42, a first built-in power distribution unit 43, a second built-in power distribution unit 44 and supporting columns 45. The first built-in power distribution unit 43 has a column housing 431, a plurality of power sockets 432, a circuit breaker 433, a cable clip 434 and a main power cable 435, and the second built-in power distribution unit 44 has a column housing 441 a plurality of power sockets 442, a circuit breaker 443, a cable clip 444, a main power cable 445 and a display interface 446. It is seen in FIG. 4 that the column housing 431 of the first built-in power distribution unit 43, the column housing 441 of the second built-in power distribution unit 44 and the two supporting columns 45 are configured between the top 41 and the bottom 42. As to the first built-in power distribution unit 43, the plurality of power sockets 432, the circuit breaker 433 and the cable clip 434 are configure on the column housing 431, where the cable clip 434 is further configured at the upper end of the column housing 431. The main power cable 435 is connected to the circuit breaker 433 and the plurality of power sockets 432 in the column housing 431 through the cable clip 434 so as to supply power to the external devices. As to the second built-in power distribution unit 44, the plurality of power sockets 442, the circuit breaker 443 and the cable clip 444 and the display interface 446 are configure on the column housing 441, where the cable clip 444 is further configured at the lower end of the column housing 441. The main power cable 445 is connected to the circuit breaker 443, the display interface 446 and the plurality of power sockets 442 in the column housing 441 through the cable clip 444 so as to supply power to the external devices. The display interface 446 can show the status of the second built-in power distribution unit 44. For example, if the display interface 446 is a display panel or a touch panel, the screen of the display interface 446 can show whether the plurality of power sockets 442 supplies power normally or it is abnormal, and also can show the type of the plurality of power sockets 442 or provide any information related to the second built-in power distribution unit 44. In FIG. 4, “C20” shown on the display interface 446 means that the second built-in power distribution unit 44 can receive power form other power sockets with IEC 320 C19 and thus can function as a power input.

The above-mentioned embodiments are only examples for illustration, and the rack with a built-in power distribution unit of the present invention can be modified. For example, the built-in power distribution unit of the present invention can be modified to have a function of supplying power in series and/or a function of distribution for three-phase input/single-phase output, to include a grounding wire for the external devices to ground, or to have two sets of cable clips and main power cables respectively configured on the upper end and the lower end of the column housing so as to have a function of arranging the cables in different ways. It is noted that prior rotatable mechanisms are mounted on the top and the bottom of the rack to be connected to the column housing of the built-in power distribution unit so as to rotate the column housing when the column housing of the built-in power distribution unit is desired to be configured in a rotatable way to change the horizontal direction of the power sockets. For example, a rotating mechanism having ratchets can provide the column housing with the function of rotating, but the column housing can be rotated in only an anticlockwise direction or only a clockwise direction due to the ratchets. The embodiments are only examples, and do not limit the rotating mechanism to any particular rotating mechanism to change the direction of the power sockets of the built-in power distribution unit. In addition, if the column housing of the built-in power distribution unit is not configured in a rotatable way, the top, the bottom, the column housing and the supporting columns can be made integrally to form the main structure of the rack. Besides, if the same built-in power distribution unit has two set of sockets, the power source of the one set can be any one socket of the other set.

Moreover, the rack with the built-in power distribution unit can exchange the positions of the built-in power distribution units and the supporting columns and/or change the number of the built-in power distribution units and the supporting columns through changing the configuration of the assembly. Namely, there are connecting mechanisms mounted on the top and the bottom, such as slots, and the connecting mechanisms connect the supporting columns to the top/the bottom and connect the column housing of the built-in power distribution unit to the top/the bottom. Therefore, the users can assemble the top, the bottom, the built-in power distribution units and the supporting columns in any combination to get the desired rack. For example, the cable clip is at the upper end of the column housing of the built-in power distribution unit initially. However, if the column is configured upside-down between the top and the bottom, the position for the main power cable to pass through the column housing changes from the upside to the downside. If the user wants to change the direction of the power sockets of the built-in power distribution unit, all the user needs to do is to horizontally rotate the column housing the desired degrees before assembling the column housing, the top and the bottom. If more power or different types of power resources are required, the rack can be configured with two built-in power distribution and two supporting columns. If the power distribution is not required, the rack can only use the supporting columns to save the cost of the built-in power distribution unit.

The present invention overcomes the space-consuming problem in the rack when the power distribution device is used, and can provide the external devices with more space in the rack for heat dissipation and maintenance. Because more than one built-in power distribution units can be used in the present invention, various power sources and various power sockets can be configured in the rack to meet the requirements for the external devices with different types of power input. Moreover, because the power sockets of the built-in power distribution unit are mounted on the column housing rather than configured in the containing space of the rack, the external devices in the rack are not obstructed by the power cables and the power cables do not affect the operation and the exterior view of the whole equipment, so as to prevent the user from cleaning up the power cables. In addition, the number, the position and the rotating direction of the built-in power distribution units can be configured/arranged in the users' demand to utilize the space in the rack efficiently.

The invention need not be limited to the disclosed embodiments and the wording/terms, and it is intended to cover various modifications and similar arrangements included within the spirit of the present invention and the scope of the appended claims.

What is claimed is:

1. A rack with a built-in power distribution unit, comprising:
a top;
a bottom;
the built-in power distribution unit having a column housing and a plurality of power sockets, wherein the column housing is rotatably configured between the top and the bottom and the plurality of power sockets are configured on the column housing; and
at least one supporting column configured between the top and the bottom, collaborating with the built-in power distribution unit to support the top, and forming a containing space with the column housing, the top and the bottom.

2. The rack as claimed in claim 1, wherein the built-in power distribution unit further comprises a cable clip configured on the column housing for a power cable to pass into the column housing therethrough.

3. The rack as claimed in claim 2, wherein the cable clip is further configured on one of an upper end and a lower end of the column housing.

4. The rack as claimed in claim 1, wherein the built-in power distribution unit further comprises a circuit breaker.

5. The rack as claimed in claim 1, wherein the built-in power distribution unit further comprises a display interface.

6. The rack as claimed in claim 5, wherein the display interface is one of a lighting unit and a display panel.

7. The rack as claimed in claim 1, wherein the plurality of power sockets has at least two types.

8. The rack as claimed in claim 1, wherein the built-in power distribution unit further comprises a grounding wire.

9. A rack with a built-in power distribution unit, comprising:
a top;
a bottom; and
a plurality of supporting columns configured between the top and the bottom and forming a containing space with the top and the bottom,
wherein, at least one of the plurality of supporting columns includes a housing and the built-in power distribution unit having a plurality of power sockets, the at least one of the plurality of supporting columns is rotatably configured between the top and the bottom, and the plurality of power sockets are configured on the housing.

10. A rack with a built-in power distribution unit, comprising:
a bottom;
the built-in power distribution unit having a column housing and a plurality of power sockets configured on the column housing; and
at least one supporting column configured between the top and the bottom,
wherein, the at least one supporting column, the column housing of the built-in power distribution unit and the bottom are configured to be capable of being assembled to form a containing space.

11. The rack as claimed in claim 10, further comprising a rotating mechanism configured to connect the column housing of the built-in power distribution unit and the bottom.

12. The rack as claimed in claim 10, wherein the bottom has a square frame.
